(19) United States
(12) Patent Application Publication
(10) Pub. No.: US 2012/0329290 A1
(43) Pub. Date: Dec. 27, 2012

(54) Substrate Placement Stage, Substrate Processing Apparatus and Method of Manufacturing Semiconductor Device

(75) Inventors: Toshiya Shimada, Toyama (JP); Kazuhiro Shimeno, Toyama (JP); Masakazu Sakata, Toyama (JP); Hidehiro Yanai, Toyama (JP); Tomihiro Amano, Toyama (JP); Yuichi Wada, Toyama (JP)

(73) Assignee: HITACHI KOKUSAI ELECTRIC INC., Tokyo (JP)

(21) Appl. No.: 13/479,441

(22) Filed: May 24, 2012

(30) Foreign Application Priority Data
May 26, 2011 (JP) 2011-117723
May 9, 2012 (JP) 2012-107668

(51) Int. Cl. B05C 13/02; H01L 21/324

(52) U.S. Cl. 438/795; 156/345.52; 257/E21.328

(57) ABSTRACT

Provided is a substrate placement stage or substrate processing apparatus which can suppress thermal deformation of the substrate placement stage when the substrate placement stage on which a substrate is placed is heated in a process chamber. The substrate placement stage includes: a heating element; a first member surrounding the heating element; and a second member covering a surface of the first member and including a placing surface for placing a substrate thereon, wherein the first member is made of a first material containing ceramics and aluminum, and the second member is made of a second material containing ceramics and aluminum, a content of the ceramics in the second material being lower than that of the first material.

### CROSS-REFERENCE TO RELATED PATENT APPLICATION

This U.S. non-provisional patent application claims priority under 35 U.S.C. §119 of Japanese Patent Application No. 2011-117723 filed on May 26, 2011 and Japanese Patent Application No. 2012-107668 and May 9, 2012, in the Japanese Patent Office, the entire contents of which are hereby incorporated by reference.

### BACKGROUND OF THE INVENTION

1. Field of the Invention

The present invention relates to a substrate processing apparatus for manufacturing a semiconductor integrated circuit device (hereinafter referred to as an IC) and the like. In particular, the present invention relates to a substrate placement stage, a substrate processing apparatus using the same, and a method of manufacturing a semiconductor device using the substrate processing apparatus, capable of suppressing thermal deformation of the substrate placement stage when the substrate placement stage on which the substrate is placed is heated in a process chamber in the substrate processing apparatus including the process chamber configured to process a semiconductor substrate (for example, a semiconductor wafer) on which a semiconductor integrated circuit is manufactured.

2. Description of the Related Art

In the related art, as disclosed in Japanese Patent Unexamined Application No. 2009-88347, it has been known that a substrate processing apparatus in which a heater is housed in a substrate placement stage on which a substrate is placed in a process chamber and the substrate is heated and processed by the heater. Since the substrate placement stage is mainly made of aluminum, such a substrate processing apparatus is usually used at a temperature equal to or less than about 400° C. in order to avoid thermal deformation in consideration of thermal resistance of the substrate placement stage. As the thermal deformation of the substrate placement stage is suppressed, the substrate placed on the substrate placement stage can be uniformly heated.

In recent years, a need for a substrate to be processed uniformly at a high temperature has arisen. To achieve this, for example, a pure aluminum-based alloy with low impurities may be used as a material of the substrate placement stage. However, when the pure aluminum-based alloy with low impurities is set to a high temperature, crystallization of the aluminum progresses on a surface of the substrate placement stage, such that wrinkle-like concave and convex portions are generated. Since variation in distance between the substrate placed on the surface of the substrate placement stage and the heater occurs due to the concave and convex portions, the substrate cannot be heated uniformly.

In addition, an A5052 aluminum alloy having high temperature resistance may be used as a material of the substrate placement stage. However, since the A5052 aluminum alloy contains magnesium (Mg), if the substrate placement stage is high-temperature condition, the magnesium (Mg) is oxidized, and the surface of the substrate placement stage may be discolored at a high temperature. When the surface is discolored, since an emission rate of heat rays emitted from the heater is changed, the heater does not raise the temperature of the substrate up to a desired temperature.

To allow the substrate to be processed at higher temperature, the substrate placement stage may be made of materials such as stainless steel or aluminum nitride (AlN). However, since these materials have a low thermal conductivity compared to aluminum, temperature uniformity is lowered when the substrate is heated. In addition, these materials may also contribute to an increase in total weight of the substrate placement stage or cost.

### SUMMARY OF THE INVENTION

It is an object of the present invention to provide a substrate placement stage or a substrate processing apparatus, or a method of manufacturing the substrate placement stage or a method of manufacturing a semiconductor device in which, when the substrate placement stage on which a substrate is placed is heated in a process chamber, the substrate can be set to a high temperature and can be uniformly heated.

According to one aspect of the present invention, there is provided a substrate placement stage including: a heating element; a first member surrounding the heating element; and a second member covering a surface of the first member and including a placing surface for placing a substrate thereon, wherein the first member is made of a first material containing ceramics and aluminum, and the second member is made of a second material containing ceramics and aluminum, a content of the ceramics in the second material being lower than that of the first material.

According to another aspect of the present invention, there is provided a substrate processing apparatus including: a process chamber configured to process a substrate; a gas supply unit configured to supply a processing gas into the process chamber; a gas exhaust unit configured to exhaust the processing gas from an inside of the process chamber; and a substrate placement stage installed in the inside of the process chamber, the substrate placement stage including: a heating element; a first member surrounding the heating element; and a second member covering a surface of the first member, wherein the first member is made of a first material containing ceramics and aluminum, and the second member is made of a second material containing ceramics and aluminum, a content of the ceramics in the second material being lower than that of the first material.

According to still another aspect of the present invention, there is provided a method of manufacturing a semiconductor device using a substrate processing apparatus including: a process chamber configured to process a substrate; a gas supply unit configured to supply a processing gas into the process chamber; a gas exhaust unit configured to exhaust the processing gas from an inside of the process chamber; and a substrate placement stage installed in the inside of the process chamber including: a heating element; a first member surrounding the heating element; and a second member covering a surface of the first member, wherein the first member is made of a first material containing ceramics and aluminum, and the second member is made of a second material containing ceramics and aluminum, a content of the ceramics in the second material being lower than that of the first material, the method including: loading the substrate into the process chamber and placing the substrate on the substrate placement stage; heating the substrate using the heating element; supplying the processing gas into the process chamber using the gas supply unit; exhausting the processing gas from the process chamber using the gas exhaust unit; and unloading the substrate from the inside of the process chamber.

According to the configuration, when a substrate placed on a substrate placement stage is heated in a process chamber, the substrate can be uniformly heated

### BRIEF DESCRIPTION OF THE DRAWINGS

FIG. 1 is an overall configuration diagram of a substrate processing apparatus, showing a conceptual diagram viewed from the top thereof according to an embodiment of the present invention.

FIG. 2 is a vertical sectional view of a portion of the substrate processing apparatus shown in FIG. 1.

FIG. 3 is a vertical sectional view of a process chamber 16a shown in FIG. 1.

FIG. 4 is a perspective view of the process chamber 16a shown in FIG. 1.

FIG. 5 is a diagram of the process chamber 16a shown in FIG. 1 from above.

FIG. 6 is a diagram for explaining a substrate holding pin 74 according to the embodiment of the present invention.

FIGS. 7A and 7B are diagrams for explaining a fixing method of a substrate placement stage according to the embodiment of the present invention.

FIG. 8 is a vertical sectional view of a substrate placement stage according to the embodiment of the present invention.

FIGS. 9A to 9C are diagrams for explaining a method of manufacturing a substrate placement stage according to the embodiment of the present invention.

FIG. 10 is a diagram for explaining a method of transferring a substrate from a process chamber 16a shown in FIG. 1

FIG. 11 is a diagram for explaining a method of transferring a substrate from the process chamber 16a shown in FIG. 1.

FIG. 12 is a diagram for explaining a method of transferring a substrate from the process chamber 16a shown in FIG. 1.

### DETAILED DESCRIPTION

In the embodiment of the present invention, as an example, a substrate processing apparatus is configured as a semiconductor manufacturing apparatus performing processing processes in a method of manufacturing a semiconductor device (IC). Hereinafter, one embodiment of the present invention will be described with reference to the drawings.

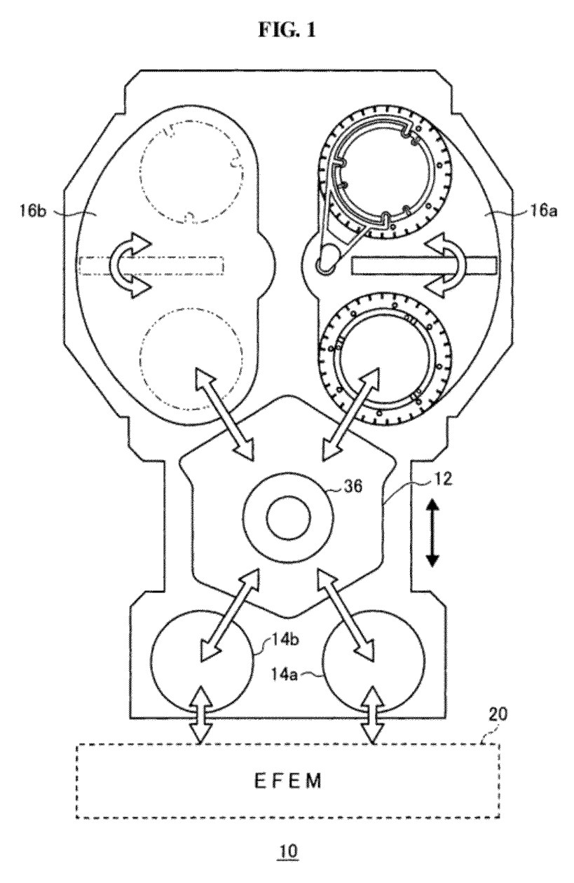

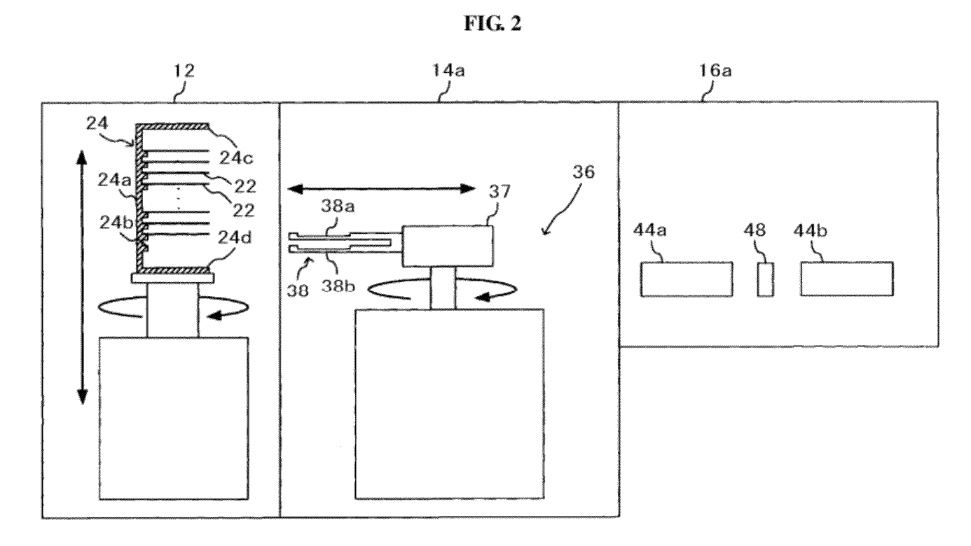

FIG. 1 is an overall configuration diagram of a substrate processing apparatus 10, showing a conceptual diagram of the substrate processing apparatus 10 from above according to an embodiment of the present invention. FIG. 2 is a vertical sectional view of a portion of the substrate processing apparatus shown in FIG. 1. As shown in FIGS. 1 and 2, in the substrate processing apparatus 10, load lock chambers 14a and 14b and two process chambers 16a and 16b are disposed, for example, around a transfer chamber 12, and an atmospheric transfer chamber 20 (EFEM: Equipment Front End Module) is disposed on an upstream side of the load lock chambers 14a and 14b to transfer a substrate between carriers such as cassettes. The transfer chamber 12 transfers the substrate in a vacuum atmosphere and the atmospheric chamber 20 transfers the substrate in the atmosphere pressure. For example, three hoops (not shown) are disposed in the atmospheric chamber 20 which are substrate accommodating vessels that accommodate 25 substrates at regular intervals in a vertical direction. In addition, an atmospheric robot (not shown) which transfers, for example, 5 substrates at a time between the atmospheric transfer chamber 20 and the load lock chambers 14a and 14b is disposed in the atmospheric chamber 20. For example, the transfer chamber 12, the load lock chambers 14a and 14b and the process chambers 16a and 16b are made of aluminum (A5052).

Meanwhile, the load lock chambers 14a and 14b are disposed at symmetrical positions with respect to each other and have the same configuration. In addition, the process chambers 16a and 16b are also disposed at symmetrical positions with respect to each other and have the same configuration. Hereinafter, the following explanation will focus on the load lock chamber 14a and the process chamber 16a.

As shown in FIG. 2, a substrate support body 24 (boat) which accommodates substrates 22, such as 25 wafers, at regular intervals in a vertical direction is installed in the load lock chamber 14a. The substrate support body 24 is made of, for example, silicon carbide and includes, and for example, three struts 24a connecting an upper plate 24c and a lower plate 24d. In an inside of the strut 24a in a longitudinal direction, for example, 25 placement portions 24b are disposed in parallel. In addition, the substrate support body 24 is configured to be moved within the load lock chamber 14a in a vertical direction (move up and down), or to be rotated about a rotation axis extending in the vertical direction. As the substrate support body 24 is moved in the vertical direction, the substrates 22 are put two at a time on an upper surface of the placement portion 24b installed at each of the three struts 24a of the substrate support body 24 by a pair of fingers 38 of a vacuum robot 36 to be described later. In addition, the substrate support body 24 is moved in the vertical direction, such that the substrates 22 are also conveyed two at a time on the pair of fingers 38 from the substrate support body 24.

The vacuum robot 36 which transfers the substrate 22 between the load lock chamber 14a and the process chamber 16a is installed in the transfer chamber 12. The vacuum robot 36 includes an arm 37 having the pair of fingers 38 including an upper finger 38a and a lower finger 38b is installed. The upper finger 38a and the lower finger 38b are configured to have, for example, the same shape, to be spaced at predetermined intervals in the vertical direction, to extend substantially horizontally in the same direction from the arm 37, and to support the substrate 22 at the same time. The arm 37 is configured to rotate about a rotation axis extending in the vertical direction, to be moved in the horizontal direction, and to enable the substrates 22 to be transferred two at a time. Substrate placement stages 44a and 44b are installed in the process chamber 16a within a similar space of a chamber 50 to be described later. A portion of a space between the substrate placement stage 44a and the substrate placement stage 44b is partitioned by a partition member 48 in the horizontal direction. Thereafter, by placing the substrates 22 on the substrate placement stages 44a and 44b through the vacuum robot 36, the process chamber 16a can perform a heat treatment simultaneously on two of the substrates 22 within the same space of the chamber 50.

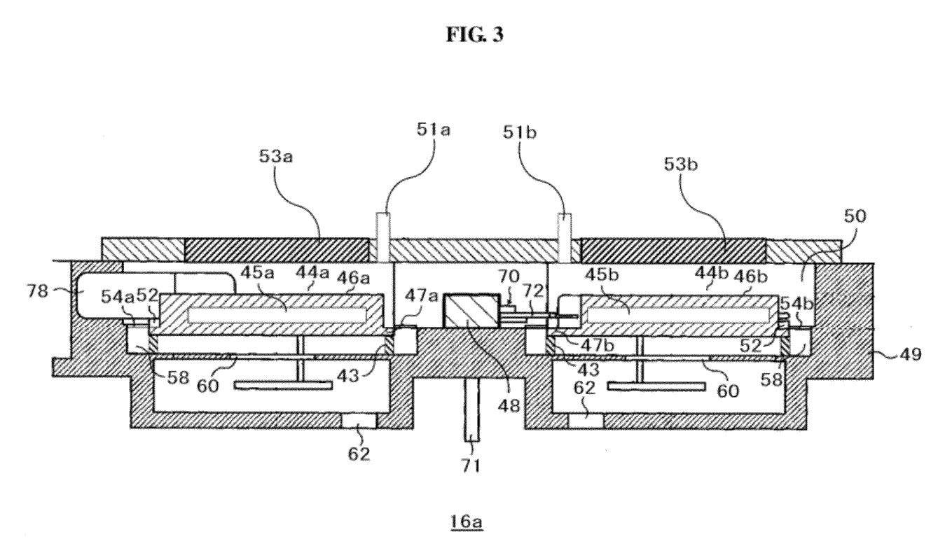

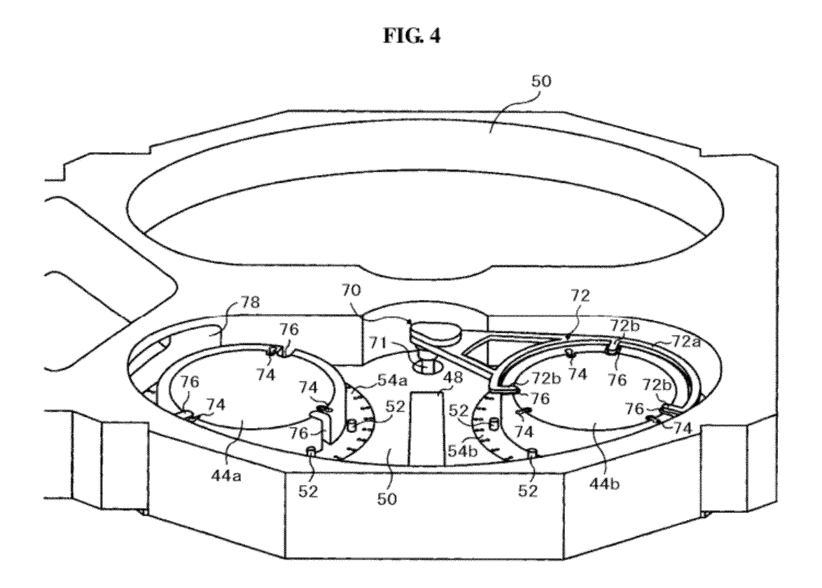

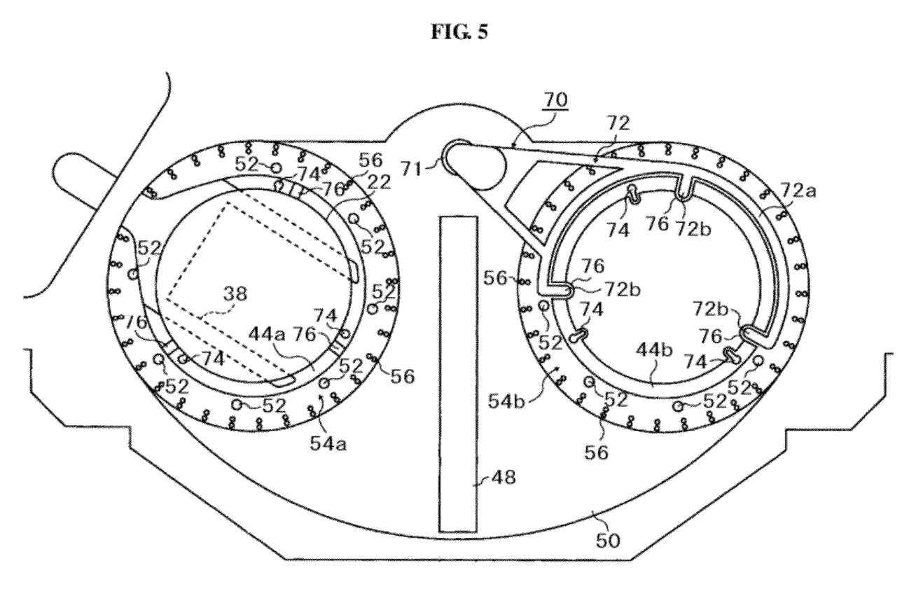

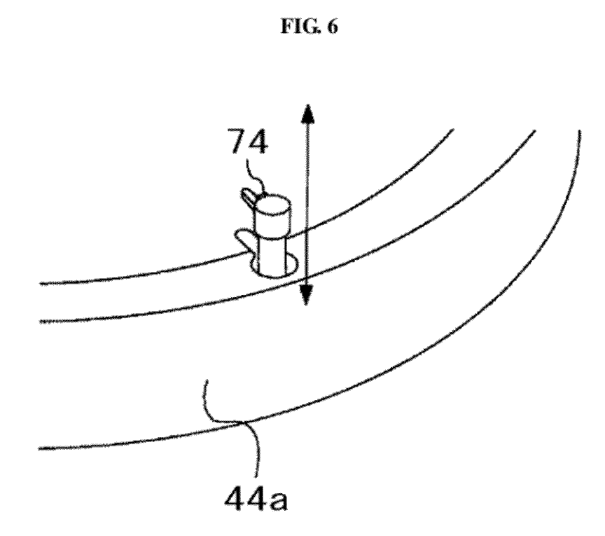

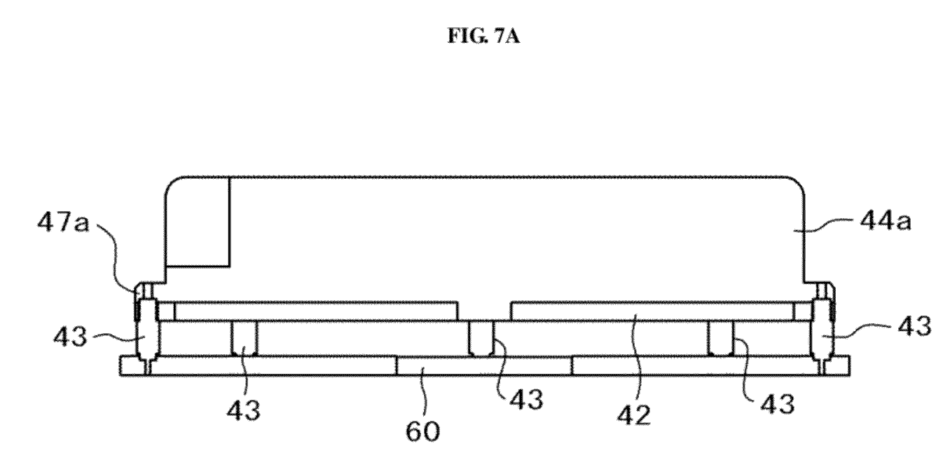

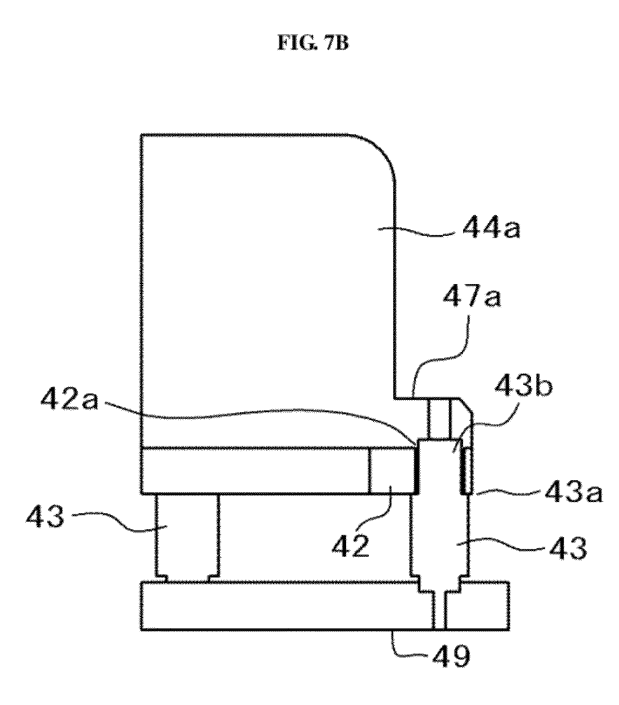

Next, an overview of the process chamber 16a will be described with reference to FIGS. 3 to 7A and 7B. FIG. 3 is a vertical sectional view of the process chamber 16a. FIG. 4 is a perspective view of the process chamber 16a. FIG. 5 is a diagram of the process chamber 16a from above. FIG. 6 is a diagram for explaining a substrate holding pin 74 according to the embodiment of the present invention. FIGS. 7A and 7B are diagrams for explaining a method of fixing the substrate placement stage 44a. As shown in FIGS. 3 to 5, the process chamber 16a includes lids 53a and 53b disposed on an upper portion of an apparatus body 49 and one chamber 50 disposed at a lower portion thereof. Gas supply units 51a and 51b supply a processing gas. The chamber 50 is configured to be able to vacuum up to, for example, about 0.1 Pa through a pump (not shown).

Substrate placement surfaces 46a and 46b which are disposed the substrate placement stages 44a and 44b are provided on surfaces close to the lids 53a and 53b. The heights of both of the substrate placement stages 44a and 44b are lower than that of the inside of the chamber 50, and both of the substrate placement stages 44a and 44b are independently disposed within the same space of the chamber 50 and fixed to the apparatus body 49 through a fixing member 52. In addition, heaters 45a and 45b, which are heating elements, are included, such that the substrate placement stages 44a and 44b can heat the substrates up to about 470° C. The substrate placement stage will be described in detail later.

Flanges 47a and 47b are installed below the substrate placement stages 44a and 44b in a different direction from the substrate placement surfaces 46a and 46b. A plurality of struts 43 fixed to the apparatus body 49 are connected to the flanges 47a and 47b, and the struts 43 support each substrate placement stage 44. A support structure will be described later.

The partition member 48 described above is disposed between the substrate placement stage 44a and the substrate placement stage 44b. The partition member 48 is made of, for example, aluminum (such as A5052 or A5056), quartz, alumina or the like and, for example, is a member having a prismatic shape attachable to the apparatus body 49.

Exhaust baffle rings 54a and 54b, which have ring shapes when viewed from above, are disposed on the substrate placement stages 44a and 44b so as to surround each periphery of thereof. The peripheries of the baffle rings 54a and 54b are provided with a plurality of hole portions 56, to perform exhaust toward a first exhaust space 58 provided around the substrate placement stages 44a and 44b. The hole portions 56 constitute a first exhaust port. In addition, a second exhaust port 60 and a third exhaust port 62, which have ring shapes when viewed from above, are installed below the substrate placement stages 44a and 44b, respectively. In addition, a gas exhaust unit that exhausts gas from the inside of the process chamber mainly includes the first exhaust port 56 or the second exhaust port 60 and the third exhaust port 62.

A robot arm 70, which can transfer the substrate 22, is disposed at one end side of the partition member 48. The robot arm 70 is configured to transfer one of the substrates 22 transferred by the arm 37 described above to the substrate placement stage 44b and to recover the transferred substrate from the substrate placement stage 44b. The robot arm 70 includes a finger 72 [the base of the finger is made of metal in order to match a position and level] made of, for example, alumina ceramics (equal to or greater than 99.6% purity) and a shaft unit 71, and a biaxial driving unit (not shown) that perform rotating and lifting is installed at the shaft unit 71. The finger 72 includes an arcuate portion 72a larger than the substrate 22, and three protruding portions 72b extending toward a center from the arcuate portion 72a are provided at predetermined intervals. When the chamber 50 has been vacuumized, the shaft portion 71 is configured to be blocked from atmosphere through a magnetic seal that is water-cooled. Meanwhile, in order to avoid completely separating the space within the chamber 50, the partition member 48 and the robot arm 70 are disposed inside the chamber 50.

Accordingly, the processing gas supplied through the gas supply units 51a and 51b flows along each substrate 22 placed on the substrate placement stages 44a and 44b within the chamber 50 and is exhausted through a hole portion 56, which is a first exhaust port, the first exhaust space 58, the second exhaust port 60 and the third exhaust port 62.

In addition, in each of the substrate placement stages 44a and 44b, the three substrate holding pins 74 penetrate in the vertical direction, such that the substrate 22 transferred through the vacuum robot 36 from the transfer chamber 12 is placed on the substrate holding pin 74. As shown in FIG. 6, the substrate holding pin 74 is configured to be elevated in the vertical direction. In addition, the substrate placement stages 44a and 44b are provided with three groove portions 76 in the vertical direction (up and down), respectively, such that the protruding portions 72b described above can be moved downward from above with respect to the upper surfaces of the substrate placement stages 44a and 44b.

Next, a method of fixing the substrate placement stages 44a and 44b and the strut 43 will be described with reference to FIGS. 7A and 7B. Since the substrate placement stage 44a and the substrate placement stage 44b each have the same structure, the substrate placement stage 44a will be described as an example. FIG. 7A is a vertical sectional view of the substrate placement stage 44a, and FIG. 7B is a partially enlarged view of FIG. 7A. The heater 45a housed in the substrate placement stage 44a is not shown. The substrate placement stage 44a includes the flange 47a having a ring shape on the periphery thereof, and the strut 43 supports the flange 47a, such that the substrate placement stage 44a is supported. The strut 43 is made of, for example, stainless steel and a lower end portion thereof is inserted and fixed into and to the apparatus body 49.

A ring 42 is installed as a fixing unit so as to support a lower portion, which is a periphery of a lower surface of the substrate placement stage 44a, of the flange 47a. The ring 42 has an integral structure of a circular shape and is made of a material that has a low thermal conductivity and is not likely to deform even at a high temperature, for example, stainless steel. The ring 42 is fixed to the lower surface of the substrate placement stage 44a. An insertion port 42a into which the strut 43 is inserted is installed on the ring 42. The strut 43 has a step portion 43a, and the ring 42 is supported by the step portion 43a. A convex portion 43b, which is an upper portion of the strut 43, passes through the insertion port 42a and is fitted in a recess portion provided at the lower portion of the flange 47a. Thus, because the ring 42 supports the substrate placement stage 44a, deformation of the substrate placement stage 44a can be suppressed even at a high temperature state in which the substrate placement stage 44a may be deformed when the substrate is heated by the heater 45a. In addition, a configuration in which the ring 42 does not fix to the lower surface of the substrate placement stage 44a is possible. However, if thermal deformation of the substrate placement stage 44a can be more firmly suppressed, a fixed configuration is also possible. In addition, a side surface of the insertion port 42a is configured so as to be in contact with a side surface of the convex portion 43b of the strut 43. By such a configuration, the strut 43 can be prevented from being tilted.

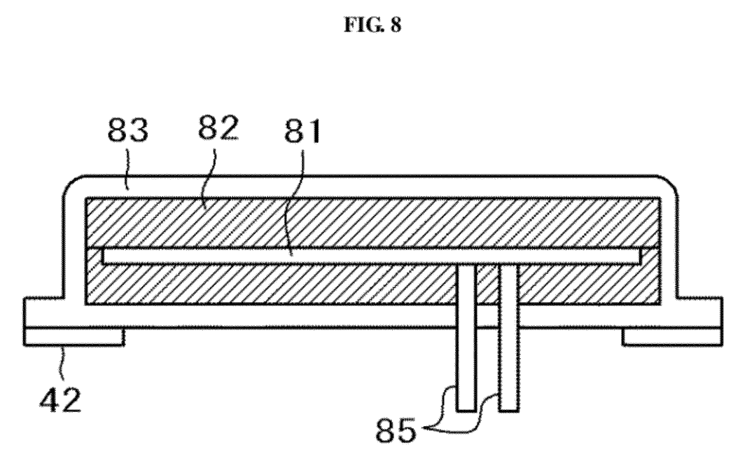

Next, a structure of the substrate placement stage 44a will be described with reference to FIG. 8. Since a structure of the substrate placement stage 44b is also similar to that of the substrate placement stage 44a, the substrate placement stage 44a will be described as an example.

In FIG. 8, reference numeral 81 is a resistance heating heater such as a nichrome wire that has a spiral shape when viewed from above, reference numeral 82 is a first member installed so as to surround the heater 81, reference numeral 83 is a second member installed so as to surround the first member, reference numeral 85 is a heater wiring pipe that accommodates a feeder supplying power to the heater 81, and the substrate placement stage 44a is supported by the ring 42. The ring 42 is a third member having thermal deformation lower than that of the first member 82 and is a widthwise annular plate as shown in FIG. 8. An upper surface of the second member 83 is configured as a placement surface on which the substrate is placed.

The first member 82 is a composite material of at least aluminum and ceramics. In this embodiment, the first member 82 is a composite material of aluminum, silicon and ceramics. A volume ratio of the ceramics in the first member 82 ranges from 20% to 50%. The ceramics are contained in the first member 82, such that thermal expansion can be reduced and thermal deformation can be suppressed, compared to aluminum. In other words, deformation of the placement surface in the substrate placement stage 44a can be prevented. Thus, the substrate placed on the substrate placement stage 44a can receive heat rays generated by the heater 81 with good reproducibility. In addition, the ceramics have a main component of alumina (Al₂O₃) or silica (SiO₂), but the ceramics also include a small amount of sodium (Na). Accordingly, if the sodium leaks into the chamber 50, this can cause metal contamination.

Here, when the proportion of ceramics in the first member 82 is higher, the following problems occur. A first problem is that, when the substrate placement stage 44a is manufactured, injection of the aluminum is difficult if the proportion of the ceramics is high, as will be described later. As a result, the aluminum of a high thermal conductivity is sparsely filled in the ceramics of a low thermal conductivity. In such a case, since a temperature distribution within the substrate placement stage 44a becomes non-uniform, heating uniformity within the surface of the substrate is lowered. In addition, since the temperature distribution within the substrate placement stage 44a is different for each substrate placement stage 44a, heating uniformity between the substrates is lowered. A second problem is that heating efficiency for the substrate is reduced, because the heat emitted from the heater 81 to the substrate is interrupted in fragments. A third problem is that a difference of thermal expansion coefficients of the first member 82 (a composite material of ceramics and aluminum) and second member 83 (an aluminum alloy) is increased. Therefore an interface of the first member 82 and the second member 83 or aluminum ally in the surface of the second member 83 is easily damaged. In consideration of avoiding the above-described problems and suppressing thermal deformation, the percentage of the ceramics in the first member 82 is set between 20% and 50%.

The second member 83 is an alloy of aluminum and silicon in this embodiment. The percentage of silicon is equal to or less than 11.7 wt % which is a eutectic point of silicon. Content of ceramics in the aluminum alloy is smaller than that of the first member 82. The ceramic component in the second member 83 may be 0 (zero). In this way, the surface of the first member 82 is covered with the second member 83, such that metal contamination generated from the first member 82 that contains many ceramics having many impurities (for example, Na) can be suppressed. In addition, as the second member 83 is an aluminum alloy in which the percentage of the silicon is equal to or less than 11.7 wt %, which is a eutectic point of silicon and aluminum, local eduction of silicon can be reduced. When the local eduction of silicon is generated, spots appear on the surface. Thus, the temperature distribution in the substrate placement stage 44a becomes non-uniform, and heating uniformity in the surface of the substrate is lowered. In addition, in consideration of ease of casting or improving strength, the second member 83 may be made of an aluminum alloy of which the percentage of silicon is 4.0 wt % or more. A rate of thermal expansion of the aluminum alloy being the second member 83 is greater than that of the composite material being the first member 82. In order to minimize the effects due to the difference in thermal expansion between the first member 82 and the second member 83, it is desirable to reduce a thickness of the second member 83. However, because there is a need to consider workability, which will be described later, the thickness of the second member 83 is set between 2 mm and 10 mm.

As mentioned in the description of FIGS. 7A and 7B, the ring 42 (third member) is made of a material that has a low thermal conductivity and does not deform even at a high temperature, for example, stainless steel. That is, the ring 42 has a lower thermal conductivity than the first member 82 or the second member 83, and does not deform at the high temperature, compared to the first member 82 or the second member 83. The third member 42 has a ring-shape, and is installed so as to support a lower portion, which is a periphery of a lower surface of the substrate placement stage 44a, of the flange 47a. The strut 43 has the step portion 43a, and the ring 42 is supported by the step portion 43a. The convex portion 43b, which is an upper portion of the strut 43, passes through the insertion port 42a and is fitted in the recess portion 43b provided at the lower portion of the flange 47a. Thus, because the substrate placement stage 44a is supported by the ring 42, deformation of the substrate placement stage 44a can be suppressed even at a high temperature state in which the substrate placement stage 44a is heated by the heater 45a and may be deformed. In addition, as described in the description of FIGS. 7A and 7B, a side surface of the insertion port 42a of the third member 42 is configured so as to be in contact with a side surface of the convex portion 43b of the strut 43. By such a configuration, the strut 43 can be prevented from being tilted. Furthermore, because the ring 42 is made of a material with a lower thermal conductivity than the first member 82 or the second member 83, local thermal leakage can be blocked from the flange 47a including the first member 82 or the second member 83. Therefore, the substrate placed on the substrate placement surface can be heated with good reproducibility.

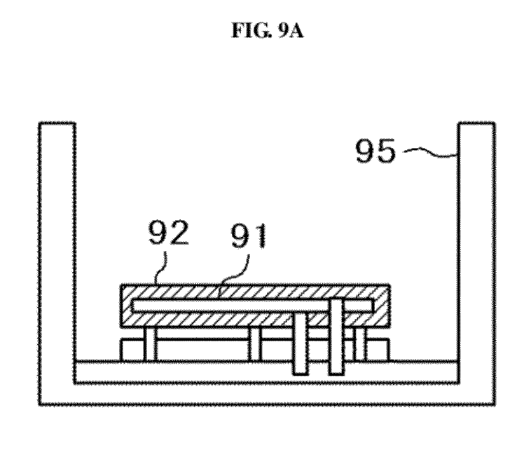

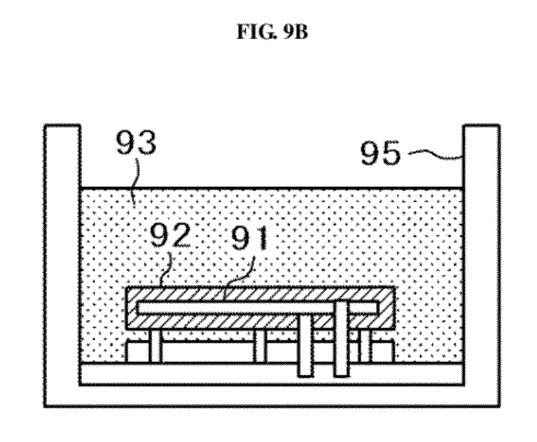

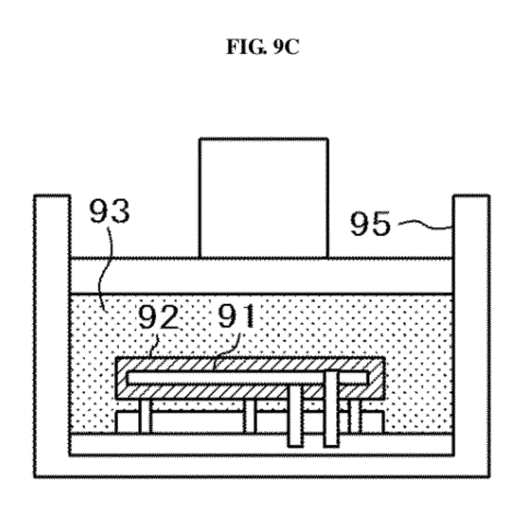

Next, a method of manufacturing the substrate placement stage 44a will be described with reference to FIGS. 9A to 9C. A method of manufacturing the substrate placement stage 44b is also the same as the method of manufacturing the substrate placement stage 44a. Here, for convenience of explanation, a method of forming the flange 47a is omitted. First, as shown in FIG. 9A, a heater pipe 91 with a built-in heater is inserted into a ceramics board 92 made of ceramics and put in a container 95. The ceramics board 92 is porous, and for example, has a porosity of about 80%. A dimension of the ceramics board 92 is set to be smaller than that of the completed substrate placement stage 44a. Next, as shown in FIG. 9B, molten aluminum 93 of 11.7 wt % or less which is a eutectic point of silicon and aluminum is poured into the container 95. The molten aluminum 93 is a molten alloy of silicon and aluminum. As mentioned above, it is desirable that the content of silicon be 4 wt % or more.

Next, as shown in FIG. 9C, the molten aluminum 93 is pressurized, such that the ceramics board 92 is impregnated with the molten aluminum 93. The pressurizing is performed because the molten aluminum 93 is not sufficiently impregnated into the ceramics board 92 only by being poured into the container 95. By pressurizing the molten aluminum 93, generation of a cavity called a “nest” can be suppressed within the alloy of silicon and aluminum formed from the molten aluminum 93. According to the processes described above, a periphery of the ceramics board 92 is covered by the second member 83, which is an alloy of silicon and aluminum formed from the molten aluminum 93. Then, the alloy of silicon and aluminum covering the periphery of the ceramics board 92 is processed to a thickness of about 2 mm to 10 mm by a process such as a cutting process. Since a dimension of the ceramics board 92 is smaller than that of the substrate placement stage 44a, the first member 82, which is a composite material of ceramics and aluminum, can be prevented from being exposed to a surface of the substrate placement stage 44a

By the method described above, the substrate placement stage in which temperature uniformity and economic efficiency are excellent can be easily achieved, and the substrate placement stage can be heated up to a temperature of, for example, 470° C. The substrate placement stage has a periphery of the heater which is covered with the first member, which is a composite material of ceramics and aluminum, and a periphery of the first member which is covered with the second member. The second member is an aluminum alloy of which the percentage of silicon is equal to or less than 11.7 wt %, which is a eutectic point of silicon and aluminum. When a temperature cycle test was performed in the substrate placement stage manufactured according to the method, occurrence of discoloration or wrinkles seen in the substrate placement stage of the aluminum alloy of the related art was not observed. In the temperature cycle test, by repeating a cycle in which the temperature was raised to 450° C., lowered to 200° C. and raised to 400° C. again, the cycle of 450° C.→200° C.→450° C. was performed 40 times.

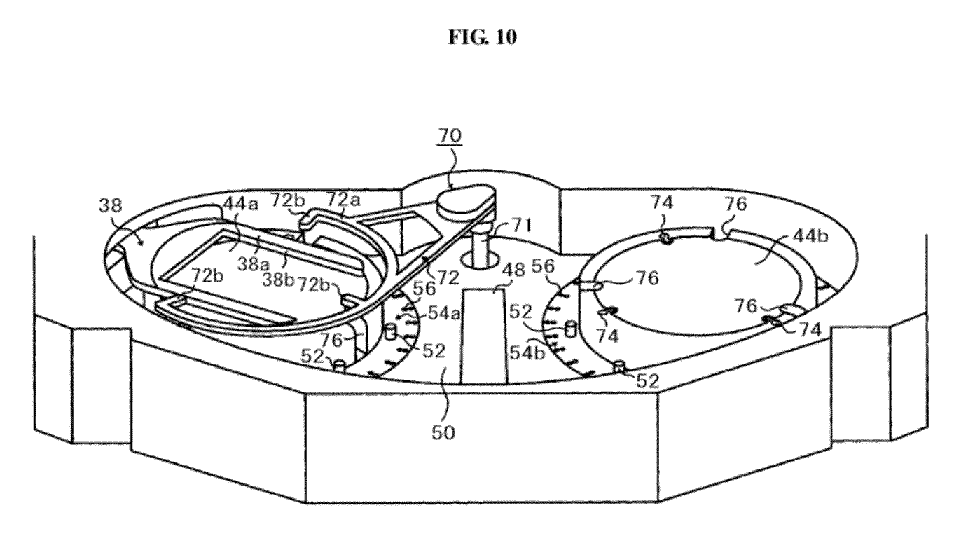

Next, an operation of transferring the substrate 22 by the robot arm 70, and a substrate processing method will be described as a process of the method of manufacturing a semiconductor device according to the embodiment of the present invention with reference to FIGS. 10 to 12. FIGS. 10 to 12 illustrate a process in which the robot arm 70 transfers the substrate 22. Meanwhile, in order to clarify the operation of the robot arm 70, the substrate 22 is not shown in FIGS. 10 to 12. First, as shown in FIG. 10, the upper finger 38a and the lower finger 38b of the pair of fingers 38 of the vacuum robot 36 each transfer substrates from the transfer chamber 12 into the chamber 50 (two substrates 22 are transferred at a time) and stop above the substrate placement stage 44a. At this time, the finger 72 of the robot arm 70 waits above the substrate placement stage 44a so as to be positioned between the two substrates 22

Then, in a state in which the pair of fingers 38 are stopped, the three substrate holding pins 74 penetrating the substrate placement stage 44a and the robot arm 70 are moved upward. Here, the substrate 22 placed on the lower finger 38b is transferred to the three substrate holding pins 74 penetrating the substrate placement stage 44a, and the substrate 22 placed on the upper finger 38a is transferred to the finger 72. The pair of fingers 38 transferring the two substrates 22 is returned to the transfer chamber 12.

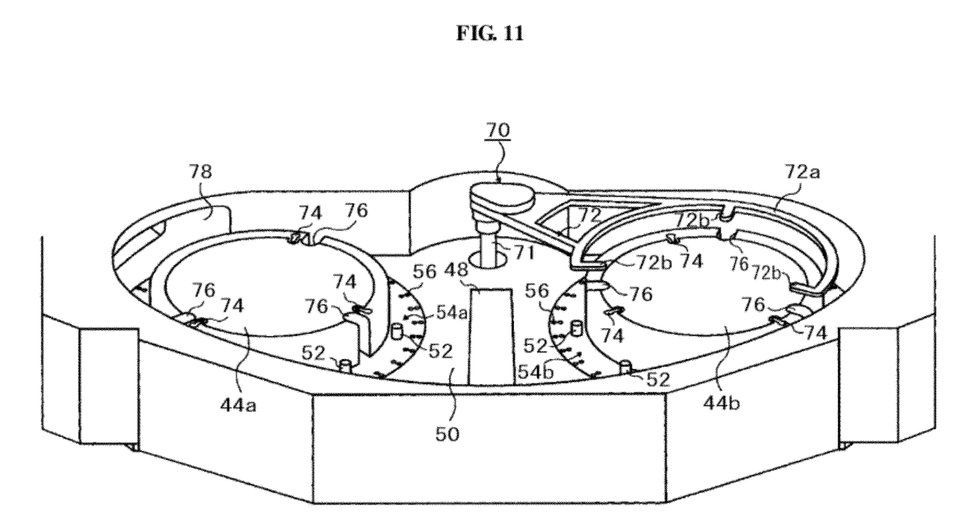

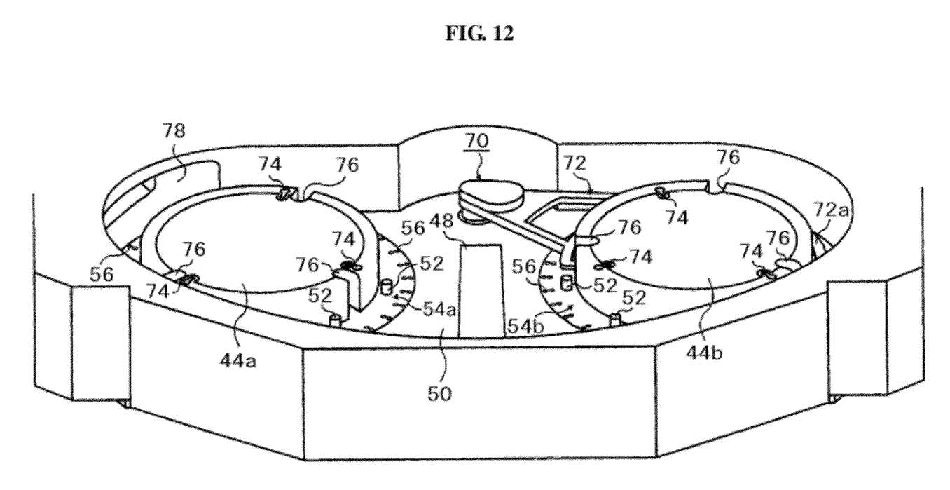

Then, as shown in FIG. 11, the finger 72 of the robot arm 70 is moved above the substrate placement stage 44b by rotation of the shaft portion 71. Then, as shown in FIG. 12, the protruding portions 72b of the finger 72 are moved downward from above along the groove portions 76 of the substrate placement stage 44b such that the substrates 22 are delivered to the three substrate holding pins 74 penetrating the substrate placement stage 44b.

Then, the finger 72 of the robot arm 70 is moved below the substrate placement surface 46b. When the finger 72 of the robot arm 70 is moved downward, the three substrate holding pins 74 penetrating the substrate placement stage 44a and the three substrate holding pins 74 penetrating the substrate placement stage 44b are moved downward, the substrate 22 transferred by the lower finger 38b and the substrate 22 transferred by the upper finger 38a are placed on the substrate placement surfaces 46a and 46b, respectively, at substantially the same time. In addition, in a state in which gas supplied from the gas supply units 51a and 51b is not inhibited from flowing downward from above, the robot arm 70 is located within the chamber 50 during the processing of the substrate 22.

The substrates 22 placed on the substrate placement surfaces 46a and 46b are heated to a desired temperature, for example, 470° C., by the heaters 45a and 45b. In parallel with the heating processing, a processing gas is supplied from the gas supply units 51a and 51b. For example, nitrogen (N₂) gas is supplied as the processing gas. In an atmosphere of the supplied processing gas, the substrates 22 are heated, and a predetermined heat treatment is performed.

When the predetermined heat treatment is finished, the processing gas is exhausted from the inside of the chamber 50. Then, the two substrates 22 are transferred from the inside of the chamber 50 to the transfer chamber 12. In this case, the robot arm 70 and the pair of fingers 38 perform operations in the reverse order of the operations described with reference to FIGS. 10 to 12

According to the embodiment described above, at least the following effects (1) to (7) may be obtained.

(1) When the substrate placement stage on which the substrate is placed is heated in the process chamber, since thermal deformation of the substrate placement stage can be suppressed by ceramics in the first member, the substrate can be heated with good reproducibility. In addition, metal contamination due to ceramics in the first member can be suppressed by the second member.

(2) Since the second member is made of a mixed material of ceramics and aluminum, a change in emission rate due to surface discoloration and occurrence of wrinkles due to crystallization can be suppressed. In addition, since deformation of the substrate placement stage can be suppressed, the substrate can be heated with good reproducibility.

(3) Since the percentage of the silicon of the second member is equal to or less than 11.7 wt %, which is a eutectic point of silicon and aluminum, local eduction of silicon can be suppressed.

(4) Since the thickness of the second member is set between 2 mm and 10 mm, the effects due to the difference of thermal expansion between the first member and the second member can be reduced and good workability can be obtained.

(5) Since at least the periphery of the lower surface of the first member or the second member can be supported by stainless steel, which is the third member having lower thermal deformation than the first member or the second member, thermal deformation of the first member or the second member can be further suppressed.

(6) Since at least the periphery of the lower surface of the first member or the second member can be supported by stainless steel, which is the third member having a lower thermal conductivity than the first member or the second member, local thermal leakage can be suppressed through the third member, and the substrate can be uniformly heated.

(7) By the method of manufacturing the substrate placement stage described above, the substrate placement stage in which the periphery of the heating element is covered with the first member, which is a composite material of ceramics and aluminum, the periphery of the first member is covered with the second member, and the content of the ceramics component is less than that of the first member 82 can be easily achieved.

In addition, it is obvious that the present invention is not limited to the embodiments described above, and various modifications are possible without departing from the scope of the present invention. In the embodiments described above, the second member is configured to surround the first member, but the second member may be configured so as to cover only a part of the substrate placement stage exposed to the processing gas supplied into the process chamber. By such a configuration, the suppression of metal contamination is slightly lowered, compared to the embodiment described above, but the substrate placement stage can be easily manufactured. In addition, in the above-described embodiments, a process performed on substrates such as wafers has been described. However, objects to be processed may be a hot mask or printed wiring substrate, an LED panel, a compact disc or a magnetic disk, etc.

This specification includes at least the following inventions.

The first invention relates to a substrate placement stage including: a heating element; a first member configured to surround the heating element; and a second member configured to cover a surface of the first member and including a placing surface for placing a substrate on one surface thereof, wherein the first member is made of a first material containing ceramics and aluminum, and the second member is made of a second material in which a content of the ceramics is lower than that of the first material and the ceramics and aluminum are contained.

As the second invention, in the substrate placement stage described in the first invention, the second member is made of a mixed material of silicon and aluminum.

As the third invention, in the substrate placement stage described in the second invention, a percentage of the silicon of the second member is equal to or less than 11.7 wt %, which is a eutectic point of silicon and aluminum

The fourth invention relates to a substrate processing apparatus including: a process chamber configured to process a substrate; a gas supply unit configured to supply a processing gas into the process chamber; a gas exhaust unit configured to exhaust the processing gas from an inside of the process chamber; and a substrate placement stage installed in the inside of the process chamber, the substrate placement stage including: a heating element; a first member surrounding the heating element; and a second member covering a surface of the first member, wherein the first member is made of a first material containing ceramics and aluminum, and the second member is made of a second material containing ceramics and aluminum, a content of the ceramics in the second material being lower than that of the first material.

As the fifth invention, in the substrate processing apparatus described in the fourth invention, the second member is configured to cover at least a part of the substrate placement stage exposed to the processing gas supplied into the process chamber.

As the sixth invention, in the substrate processing apparatus described in the fourth invention or the fifth invention, the substrate processing apparatus further includes a third member configured to support at least a periphery of a lower surface of the first member and having lower thermal deformation than the first member.

As the seventh invention, in the substrate processing apparatus described in the fourth invention or the fifth invention, the substrate processing apparatus further includes a third member supporting at least a periphery of a lower surface of the first member and having a lower thermal conductivity than the first member.

The eighth invention relates to a method of manufacturing a substrate placement stage, the method including: inserting a heating element into a ceramic material; immersing the ceramics material into which the heating element is inserted in molten aluminum; and impregnating the ceramics material immersed in the molten aluminum by pressurizing the molten aluminum.

The ninth invention relates to a method of manufacturing a semiconductor device using a substrate processing apparatus including: a process chamber configured to process a substrate; a gas supply unit configured to supply a processing gas into the process chamber; a gas exhaust unit configured to exhaust the processing gas from an inside of the process chamber; and a substrate placement stage installed in the inside of the process chamber including: a heating element; a first member surrounding the heating element; and a second member covering a surface of the first member, wherein the first member is made of a first material containing ceramics and aluminum, and the second member is made of a second material containing ceramics and aluminum, a content of the ceramics in the second material being lower than that of the first material, the method including: loading the substrate into the process chamber and placing the substrate on the substrate placement stage; heating the substrate using the heating element; supplying the processing gas into the process chamber using the gas supply unit; exhausting the processing gas from the process chamber using the gas exhaust unit; and unloading the substrate from the inside of the process chamber.

1. A substrate placement stage comprising:
a heating element;
a first member surrounding the heating element; and
a second member covering a surface of the first member and including a placing surface for placing a substrate thereon,
wherein the first member comprises a first material containing ceramics and aluminum, and the second member comprises a second material containing ceramics and aluminum, a content of the ceramics in the second material being lower than that of the first material.

2. A substrate processing apparatus comprising:
a process chamber configured to process a substrate; a gas supply unit configured to supply a processing gas into the process chamber; a gas exhaust unit configured to exhaust the processing gas from an inside of the process chamber; and a substrate placement stage installed in the inside of the process chamber,
the substrate placement stage comprising:
a heating element;
a first member surrounding the heating element; and
a second member covering a surface of the first member,
wherein the first member comprises a first material containing ceramics and aluminum, and the second member comprises a second material containing ceramics and aluminum, a content of the ceramics in the second material being lower than that of the first material.

3. The apparatus according to claim 2, further comprising a third member supporting at least a periphery of a lower surface of the first member and having a lower thermal conductivity than the first member.

4. A method of manufacturing a semiconductor device using a substrate processing apparatus comprising: a process chamber configured to process a substrate; a gas supply unit configured to supply a processing gas into the process chamber; a gas exhaust unit configured to exhaust the processing gas from an inside of the process chamber; and a substrate placement stage installed in the inside of the process chamber comprising: a heating element; a first member surrounding the heating element; and a second member covering a surface of the first member, wherein the first member comprises a first material containing ceramics and aluminum, and the second member comprises a second material containing ceramics and aluminum, a content of the ceramics in the second material being lower than that of the first material, the method comprising:
loading the substrate into the process chamber and placing the substrate on the substrate placement stage;
heating the substrate using the heating element;
supplying the processing gas into the process chamber using the gas supply unit;
exhausting the processing gas from the process chamber using the gas exhaust unit; and
unloading the substrate from the inside of the process chamber.
